(19) United States
(12) Patent Application Publication
(10) Pub. No.: US 2013/0278331 A1
(43) Pub. Date: Oct. 24, 2013

(54) Reference Potential Converter Circuit

(71) Applicant: INTERCHIP CORPORATION, Shiroi-shi (JP)

(72) Inventor: Masaaki Kamiya, Shiroi-shi (JP)

(21) Appl. No.: 13/867,477

(22) Filed: Apr. 22, 2013

(30) Foreign Application Priority Data
Apr. 23, 2012 (JP) 2012-098212

(51) Int. Cl. H03F 1/00

(52) U.S. Cl. CPC H03F 1/00
USPC 330/69

(57) ABSTRACT

A reference potential converter circuit comprises: a first resistor (resistance value R1) serving as a feedback resistor for an operational amplifier; a second resistor (resistance value R2) connected to the first resistor and a reference voltage; and a third resistor (reference value R3) and a fourth resistor (reference value R4) connected between a power supply and ground. A difference voltage between Vout and Vref is divided by an R1/R2 ratio and applied to an inverting input terminal of the operational amplifier. A power supply voltage is divided by an R3/R4 ratio and applied to a non-inverting input terminal of the operational amplifier. The R1/R2 ratio and the R3/R4 ratio are equal.

The entire disclosure of Japanese Patent Application No. 2012-098212 filed Apr. 23, 2012 is expressly incorporated by reference herein.

### TECHNICAL FIELD

This invention relates to a reference potential converter circuit useful, particularly, when applied in converting a reference voltage of bandgap reference.

### BACKGROUND ART

An integrated circuit utilizes a reference voltage Vref generated by a reference voltage generator circuit. As this type of reference voltage generator circuit, a bandgap reference circuit is widely used. The bandgap reference circuit generates a bandgap voltage through utilization of two bipolar transistors. Since the bandgap reference voltage shows very small temperature dependence, it is often used when a stable voltage reference is required.

The bandgap reference circuit has occupied a relatively large area in the integrated circuit, so that it is not preferable to prepare more than one bandgap reference circuits for different potential references, such as a ground potential reference and a power supply voltage reference. With a general CMOS integrated circuit, in particular, the bipolar transistor usable in the bandgap reference circuit is either an NPN transistor or a PNP transistor depending upon IC substrate. Hence, the reference voltage is naturally produced relative to only one reference potential, either the ground potential or the power supply voltage.

Some integrated circuits, on the other hand, often need two kinds of reference voltages. One is based on a power supply voltage and the other on the ground potential.

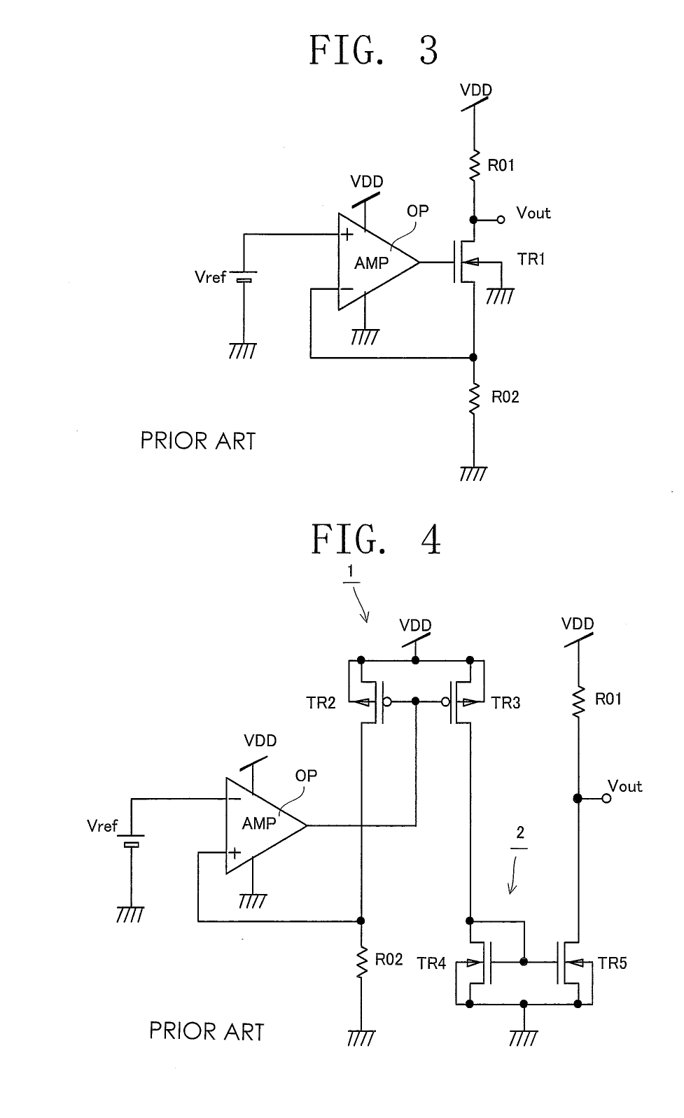

A reference potential converter circuit as shown in FIG. 3 is conceivable as a circuit which converts the reference voltage from the ground reference potential to the power supply voltage. The reference potential converter circuit outputs a converted reference voltage from Vout. A resistor R01 (resistance value is also expressed as R01), an NMOS transistor TR1 and a resistor R02 (resistance value is also expressed as R02) are connected in series between a power supply voltage VDD and a ground potential GND and the same current flows through these elements. A ground-based reference voltage Vref is applied to a non-inverting input terminal of an operational amplifier OP, while a voltage between the source of the NMOS transistor TR1 and the resistor R02 is applied to an inverting input terminal of the operational amplifier OP. Thus, the operational amplifier OP controls the gate voltage of the NMOS transistor TR1 by its output voltage so that the voltage applied to its inverting input terminal becomes the reference voltage Vref. As a result, the output voltage Vout is presented by the following equation (1):

Vout=VDD−(R01/R02)×Vref (1)

The equation (1) shows that a ground-based reference voltage Vref is converted to a reference voltage based on the power supply voltage VDD with a multiplying factor of (R01/R02).

Such a reference potential converter circuit, however, poses the problem that reduction of the operating voltage VDD is difficult. Thus, the reference potential converter circuit cannot be applied to a low voltage circuit. This is because the power supply voltage VDD, at least, needs to be higher than the sum of the voltage drop of the resistor R01 and the voltage drop of the resistor R02.

A reference potential converter circuit as shown in FIG. 4 is conceivable as one which can solve the problem on the operating voltage reduction. As shown in FIG. 4, in the reference potential converter circuit, the output voltage of an operational amplifier OP to the gates of PMOS transistors TR2, TR3 constituting a current mirror like circuit 1. Here a current from PMOS transistor TR2 and a current from PMOS transistor TR3 are proportional each other. The current from PMOS transistor TR2 flows into R02 and the current from PMOS transistor TR3 flows into R01 through the current mirror circuit 2 constituted by NMOS transistors TR4, TR5. Consequently, an output voltage Vout can be the reference voltage based on a power supply voltage VDD. In FIG. 4, the same parts as in FIG. 3 are assigned the same numerals or symbols as in FIG. 3, and duplicate explanations are omitted.

However, such a reference potential converter circuit requires 4 additional transistors for constituting the circuit. As a result, noises due to these transistors tend to be superposed on the reference voltage, thereby arousing the problem that the quality of the reference voltage greatly deteriorates.

Patent Document 1 is present as a publicly known document concerned with a power supply voltage-based reference voltage and a ground-based power supply voltage.

### PRIOR ART DOCUMENTS

### Patent Documents

[Patent Document 1] JP-A-2003-297086

### SUMMARY OF THE INVENTION

### Problems to be Solved by the Invention

The present invention has been accomplished in the light of the above-mentioned conventional technologies. It is an object of the present invention to provide a reference potential converter circuit which can convert a reference voltage based on a reference potential into another reference voltage based on another reference potential.

### Means for Solving the Problems

A first aspect of the present invention, which solves the above-mentioned problems, is a reference potential converter circuit, comprising: a first resistor connected to an output and an inverting input of an operational amplifier which worked as a feedback resistor, and a second resistor connected to the inverting input of the operational amplifier and a reference voltage terminal; and a third resistor and a fourth resistor connected to each other in series and connected between a power supply and ground, wherein a point of connection between the third resistor and the fourth resistor is connected to a non-inverting input terminal of the operational amplifier; a ratio between a resistance value of the first resistor and a resistance value of the second resistor, and a ratio between a resistance value of the third resistor and a resistance value of the fourth resistor are equal to each other; and the reference voltage is obtained by a bandgap reference circuit.

According to the first aspect, using a reference voltage based on a ground potential, a reference voltage based on a power supply voltage is obtained at the output terminal of the operational amplifier. Or, using a reference voltage based on a power supply voltage, a reference voltage based on a ground potential is obtained at the output terminal of the operational amplifier. Besides, the reference voltage after reference potential conversion can possess the same temperature characteristics as the original reference voltage.

A second aspect of the present invention is the reference potential converter circuit according to the first aspect, wherein the resistance values of the first to fourth resistors are identical.

According to the second aspect, the first to fourth resistors can be constructed in the same configuration. Thus, they can be produced most simply.

### Effects of the Invention

According to the present invention, the reference voltage converted into any reference potential can be easily obtained as the output voltage of the present circuit.

If the reference voltage is obtained by the bandgap reference circuit, the reference voltage after reference potential conversion also has very stable characteristics in a wide temperature range.

Furthermore, the reference potential converter circuit of the present invention outputs the same reference voltage as the reference potential converter circuit shown in FIG. 3. However, the former circuit of the present invention, in contrast with the latter circuit of FIG. 3, can expand the range of the power supply voltage necessary for circuit operation, and thus can be applied to a low voltage operation. Compared with the reference potential converter circuit shown in FIG. 4, the circuit of the present invention can dramatically reduce a noise contained in the reference voltage after reference potential conversion. This is because the transistor as a noise source is used only inside the operational amplifier, which operates under a negative feedback systems.

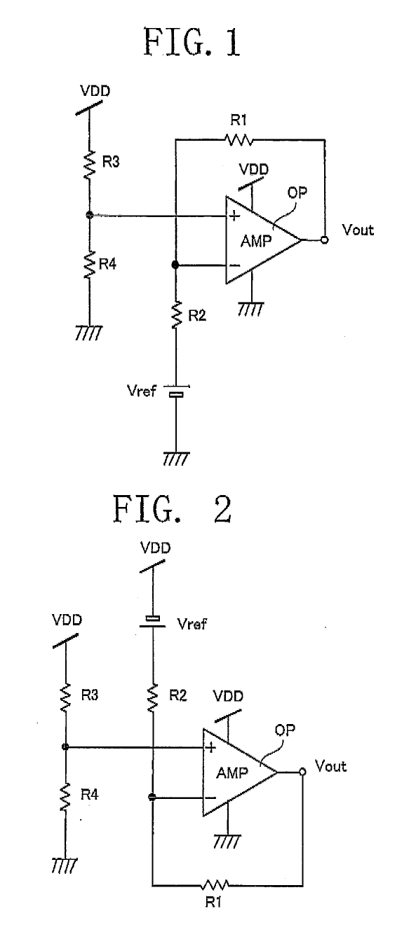

### BRIEF DESCRIPTION OF THE DRAWINGS

[FIG. 1] is a circuit diagram showing a reference potential converter circuit according to a first embodiment of the present invention.

[FIG. 2] is a circuit diagram showing a reference potential converter circuit according to a second embodiment of the present invention.

[FIG. 3] is a circuit diagram showing an example of the reference potential converter circuit according to the prior art.

[FIG. 4] is a circuit diagram showing another example of the reference potential converter circuit according to the prior art.

### MODE FOR CARRYING OUT THE INVENTION

The embodiments of the present invention will be described in detail based on the accompanying drawings.

FIG. 1 is a circuit diagram showing a reference potential converter circuit according to the first embodiment of the present invention. As shown in this drawing, a first resistor R1 (resistance value is also expressed as R1) connected to an output and an inverting input of an operational amplifier OP, a second resistor R2 connected to the inverting input of the operational amplifier and a reference voltage Vref. In this case, the reference voltage Vref is based the ground potential.

On the other hand, a power supply voltage VDD is divided by a third resistor R3 (resistance value is also expressed as R3) and a fourth resistor R4 (resistance value is also expressed as R4) and applied to a non-inverting input of the operational amplifier OP.

In the present embodiment, moreover, the resistance ratio between the first and second resistances (R1/R2) and the resistance ratio between the third and fourth resistances (R3/R4) are equal. As the reference voltage Vref, an output voltage of a bandgap reference circuit is assumed.

In the present embodiment described above, an output voltage Vout is given by said equation (1):

The equation (1) shows that the ground-based reference voltage Vref is converted to the reference voltage based on the power supply voltage VDD, with (R1/R2) multiplying factor. Here, (R1/R2) is a constant defined by the resistance values R1, R2.

Hence, the temperature characteristics of the reference potential after conversion can keep that of the original reference voltage Vref.

FIG. 2 is a circuit diagram showing a reference potential converter circuit according to the second embodiment of the present invention. The reference potential converter circuit according to the present embodiment converts a reference voltage Vref based on a power supply voltage VDD into a reference potential based on ground potential. In the present embodiment, as shown in the drawing, the reference voltage Vref based on the power supply voltage VDD is supplied to one end of a second resistor R2. This is the only difference from the embodiment of FIG. 1, and the other features are the same as those in FIG. 1. In FIG. 2, therefore, the same parts as in FIG. 1 are assigned the same numerals or symbols as in FIG. 1, and duplicate explanations are omitted.

In the present embodiment mentioned above, an output voltage Vout is given by the following equation (2):

Vout=(R1/R2)×Vref (2)

The equation (2) shows that the reference voltage Vref based on the power supply voltage VDD is converted to the reference voltage based on the ground potential with multiplying factor (R1/R2).

According to the present embodiment, as described above, the reference voltage Vref based on the power supply voltage can be easily converted into the ground-based reference potential.

In the present embodiment as well, the temperature characteristics of the reference voltage after conversion is kept as before conversion.

In the above embodiments, the relation (R1/R2)=(R3/R4) holds for the resistance values R1 to R4 of the first to fourth resistors R1 to R4. To produce the present circuit in the easiest manner, it suffices that R1=R3 and R2=R4.

### INDUSTRIAL APPLICABILITY

The present invention can be utilized effectively in industrial fields where integrated circuits requiring stable reference voltages are produced and sold.

### Explanations of Letters or Numerals

R1 to R4 First to fourth resistors

OP Operational amplifier

Vref Reference voltage

VDD Power supply voltage

Vout output voltage

1. A reference potential converter circuit, comprising:
a first resistor connected to an output and an inverting input of an operational amplifier which worked as a feedback resistor, and a second resistor connected to the inverting input of the operational amplifier and a reference voltage terminal; and
a third resistor and a fourth resistor connected to each other in series and connected between a power supply and ground,
wherein a point of connection between the third resistor and the fourth resistor is connected to a non-inverting input terminal of the operational amplifier;
a ratio between a resistance value of the first resistor and a resistance value of the second resistor, and a ratio between a resistance value of the third resistor and a resistance value of the fourth resistor are equal to each other; and
the reference voltage is obtained by a bandgap reference circuit.

2. The reference potential converter circuit according to claim 1, wherein
the resistance values of the first to fourth resistors are identical.
